(19) United States
(12) Patent Application Publication
(10) Pub. No.: US 2024/0326199 A1
(43) Pub. Date: Oct. 3, 2024

(54) TEXTURING THE INTERIOR OF THE WORKPIECE

(71) Applicant: ASM IP Holding B.V., Almere (NL)

(72) Inventors: Iordan Iordanov, Tempe, AZ (US); Osama Khalil, Chandler, AZ (US)

(21) Appl. No.: 18/620,600

(22) Filed: Mar. 28, 2024

Related U.S. Application Data
(60) Provisional application No. 63/456,078, filed on Mar. 31, 2023.

(51) Int. Cl. B24C 1/08

(52) U.S. Cl. CPC B24C 1/08

(57) ABSTRACT

Methods and apparatuses for texturizing the interior surfaces of a workpiece are described. By harnessing abrasive material contained within the workpiece, coatings that may have accumulated over time can be removed, and the original texture of the interior surfaces may be restored. One or more external energy sources such as vibratory, acoustical, or electrical energy may be used to mobilize the abrasive material and abrade the interior surfaces. The abrasive material may take the form of either abrasive dry grit or an abrasive aqueous slurry.

### CROSS-REFERENCE TO RELATED APPLICATION(S)

This application claims the benefit of U.S. Provisional Application 63/456,078 filed on Mar. 31, 2023, the entire contents of which are incorporated herein by reference.

### TECHNICAL FIELD

The present disclosure generally relates to an apparatus and a method for manufacturing semiconductor devices.

### BACKGROUND

Small diameter tubing or conduits used in reaction chambers for semiconductor manufacturing may require interior roughness to improve film adhesion to surfaces. Coatings that develop over time on the interior surfaces of the conduits may negatively impact fluid systems by obstructing the flow area or changing the texture of the surfaces. Texturing influences particle generation, making it necessary for some conduits to have a predetermined surface texture for reliable operation. However, removing the coatings from the interior surfaces of small diameter conduits or those with complex geometries is challenging. Standard industrial processes, such as traditional blast cabinets, force abrasive materials into workpieces. However, these standard processes may provide inconsistent results along the length of workpieces. For instance, using a nozzle to flow pressurized abrasive material through a tube-shaped workpiece may result in non-uniform texturing along the tube's length (e.g., significant abrading near apertures of the workpiece but insignificant abrading at an interior of the workpiece). Additionally, traditional blast cabinets cannot be effectively used with tubes that have complex geometries. For example, conduits of a system may need to be refurbished to restore a predetermined surface texture to the interior surfaces of the conduits. To remove undesired particles or coatings from interiors, straight conduits may be effectively reamed and/or blasted. Short conduits, regardless of their shape, may be hydrohoned. However, longer conduits with curved sections may be difficult to refurbish as the effect of blasting decreases with each curve of the conduit. Further, in some situations, even these approaches may be insufficient to restore original predetermined surface textures of the conduits' interior surfaces.

### SUMMARY

The following summary presents a simplified summary of certain features. The summary is not an extensive overview and is not intended to identify key or critical elements.

Methods are described for texturing the interior of the workpiece. In one aspect, a method may comprise injecting a first material into a cavity of a workpiece, wherein the workpiece comprises one or more interior walls that form the cavity, encasing the workpiece in a vessel, and transferring energy, via the vessel, to the first material in the cavity such that the first material abrades the one or more interior walls of the workpiece. The transferring energy may comprise powering a linear motor, or powering a rotary motor. The first material may comprise an abrasive grit or an abrasive slurry. The method may further comprise at least partially filling the vessel with a second material, wherein the second material is less abrasive than the first material. The first material comprises a ferrofluid material, wherein the ferrofluid material comprises a ferrofluid mixed with one of alumina, zirconia, silicon carbide, or silicon oxide, or a ferrofluid mixed with iron particles coated with one of alumina, zirconia, silicon carbide, or silicon oxide. The method may further comprise injecting a second material into the vessel, wherein the first material comprises one of alumina, zirconia, silicon carbide, or silicon oxide, the first material is more abrasive than the second material, and the second material comprises one of a synthetic fluoropolymer of tetrafluoroethylene, nylon, or polyethylene. The one or more interior walls of the workpiece may form a tube with a diameter less than 13 mm, wherein the tube includes one or more bends, non-circular flow areas, or variable flow areas. The method may further comprise sealing openings of the cavity of the workpiece after injecting the first material so that the workpiece holds the first material inside the cavity. The transferring energy may comprise vibrating the vessel and periodically alternating clockwise rotations and counter-clockwise rotations of the vessel. The transferring energy may comprise simultaneously applying an electromagnetic field to the workpiece and rotating the vessel. The abrading the one or more interior walls may comprise uniformly texturizing a surface of the one or more interior walls of the workpiece, wherein the uniformly texturizing may comprise one of restoring a pre-existing texture on the surface, creating a new texture on the surface, or polishing the surface. The method may further comprise determining a coarseness degree, of a desired texture, on a surface of the one or more interior walls of the workpiece, and based on the determining, adjusting at least one of an abrasiveness degree of the first material, a duration of the transferring energy, a movement pattern of the vessel, or a degree of the transferred energy. The transferring energy may comprise determining an axis of a portion of the workpiece, wherein the workpiece comprises a plurality of portions, each portion having a right cylindrical shape, joined together to form an irregular shape, each portion having an axis that is a line segment joining two centers of two parallel circular bases of each right cylindrical-shaped portion, and simultaneously, for at least one portion of the plurality of portions: vibrating the vessel in a direction perpendicular to an inside wall of the at least one portion of the plurality of portions, and rotating the vessel such that the workpiece rotates about the axis of the at least one portion, and wherein a duration of simultaneously vibrating the vessel and rotating the vessel is proportional to a volume of the at least one portion. The transferring energy may comprise determining an axis of a portion of the workpiece, wherein the workpiece may comprise a plurality of portions, each portion having a right cylindrical shape, joined together to form an irregular shape, each portion having an axis that is a line segment joining two centers of two parallel circular bases of each right cylindrical-shaped portion, applying an electromagnetic field in a direction perpendicular to one or more inside walls of a portion of the plurality of portions, wherein the first material in the cavity of the workpiece comprises a ferrofluid material, rotating the vessel such that the workpiece rotates about the axis of the portion at the same time as the applying, and after a period, processing a next portion of the plurality of portions by repeating the determining, applying, and rotating until all portions of the plurality of portions are processed, wherein the period is proportional to a volume of a corresponding portion.

In another aspect, a method may comprise injecting a ferrofluid material in a cavity of a workpiece, wherein the workpiece comprises a plurality of portions, each portion having a right cylindrical shape, joined together to form an irregular shape of the workpiece, each portion having an axis that is a line segment joining two centers of two parallel circular bases of each right cylindrical-shaped portion, determining an axis of a portion of the plurality of portions, rotating the workpiece about the axis of the portion, applying an electromagnetic field along a contour line of the portion at the same time as the rotating, and after a period, processing a next portion of the plurality of portions by repeating the determining, rotating, and applying until all of the plurality of portions are processed, wherein the period is proportional to a volume of a corresponding portion. The applying the electromagnetic field may comprise programming a five-axis robot with an electromagnet end effector to follow the contour line of the portion. The applying the electromagnetic field may comprise programming a series of electromagnet transducers to turn on sequentially, thereby creating a wavefront inside the portion, or cyclically varying strength of the series of electromagnet transducers, wherein the strength of each of the series of electromagnet transducers is adjustable.

In another aspect, a method may comprise injecting a ferrofluid material in a cavity of a workpiece, wherein the workpiece comprises a plurality of portions, each portion having a right cylindrical shape, joined together to form an irregular shape of the workpiece, each portion having an axis that is a line segment joining two centers of two parallel circular bases of each right cylindrical-shaped portion, applying an electromagnetic field along a contour line of a portion of the plurality of portions, and after a period, processing a next portion of the plurality of portions by repeating the applying until all of the plurality of portions are processed, wherein the period is proportional to a volume of a corresponding portion. The applying the electromagnetic field may comprise moving, by a robot, an electromagnet along the contour line of the portion while rotating or vibrating the portion about an axis of the portion. The method may further comprise placing the workpiece in a vessel, wherein the vessel may be moved or vibrated by at least one of a linear motor or a rotary motor. The ferrofluid material may comprise a ferrofluid and suspended particles of one of alumina, zirconia, silicon carbide, or silicon oxide, or a ferrofluid and suspended iron particles coated with one of alumina, zirconia, silicon carbide, or silicon oxide.

Additional aspects, configurations, embodiments, and examples are described in more detail below.

### BRIEF DESCRIPTION OF DRAWINGS

Some features are shown by way of example, and not by limitation, in the accompanying drawings. In the drawings, like numerals reference similar elements.

FIG. 1 shows an example of a cross-sectional view of a vessel containing a workpiece.

FIG. 2A shows examples of various movements that may be applied to the workpiece to texturize its surfaces.

FIG. 2B shows examples of various movements that may be applied to the workpiece to texturize its surfaces.

FIG. 3 shows an example of an electromagnet configured to apply an electromagnetic field to oscillate abrasive material for abrading the surfaces of the workpiece.

FIG. 4 shows examples of workpieces having irregular shapes.

FIGS. 5A, 5B, 5C, and 5D shows examples of texturizing procedures.

FIG. 6 shows an example of a robot equipped with an electromagnet end effector.

FIG. 7 shows an example of a plurality of magnetic elements with variable electromagnetic fields for texturizing non-uniform shaped parts.

FIG. 8A shows an example of a flow path through a manifold.

FIG. 8B shows a top isometric view of a lower block of the manifold.

FIG. 8C is a schematic view of a reactor including the manifold.

FIG. 9 shows a flowchart outlining the steps involved in an example method for texturizing a workpiece.

It will be recognized by the skilled person in the art, given the benefit of this disclosure, that the exact arrangement, sizes, and positioning of the components in the figures are not necessarily to scale or required.

### DETAILED DESCRIPTION

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, the expression “at least one of a, b, and c” may include ‘a only’, ‘b only’, ‘c only’, ‘a and b’, ‘a and c’, ‘b and c’, and/or ‘all of a, b, and c’.

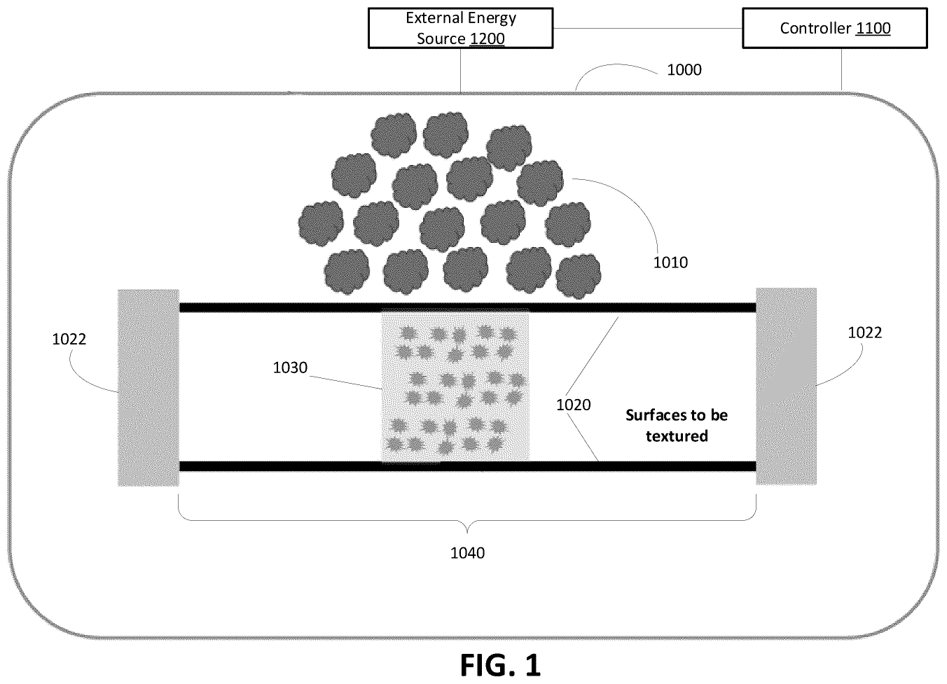

FIG. 1 shows an example of a cross-sectional view of a vessel containing a workpiece. The vessel 1000 may include non-abrasive material 1010 (e.g., a synthetic fluoropolymer of polytetrafluoroethylene (PTFE) or tetrafluoroethylene (TFE), nylon, polyethylene, liquid, or gas, etc.). The workpiece 1040 may have a tube shape with regular or irregular dimensions. Abrasive material 1030 (e.g., abrasive dry grit or abrasive grit, abrasive aqueous slurry, and/or other abrasive mixture) may be placed inside the workpiece 1040. The abrasive material 1030 may be in the form of abrasive dry grit or abrasive aqueous slurry made from materials like aluminum oxide (Al₂O₃,), silicon carbide (SiC), and/or other abrasive components. Further, the abrasive components may be provided as homogeneous materials (e.g., particles of Al₂O₃, SiC, and/or other abrasive component) or as heterogeneous materials (e.g., Al₂O₃, SiC, and/or other abrasive components coating another material). In some examples, the abrasive material 1030 may comprise Al₂O₃ and/or SiC coatings of ferrous particles. In other examples, the abrasive material 1030 may comprise ferrous coatings of Al₂O₃ and/or SiC particles. In yet other examples, the abrasive material 1030 may comprise a ferrofluid in which Al₂O₃, SiC, and/or other abrasive components are suspended.

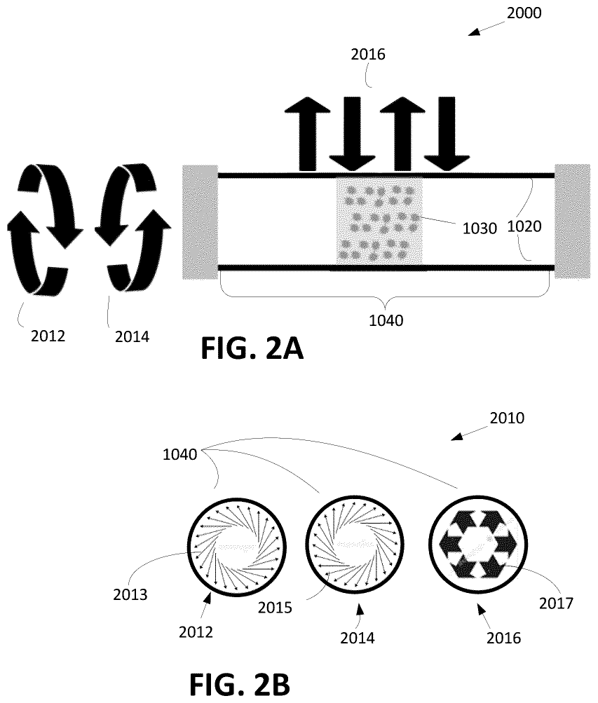

Referring to FIG. 1, the workpiece 1040 may be sealed with abrasion-resistant caps 1022. Alternatively or additionally, the abrasion-resistant caps 1022 may be attached to side interior walls of the vessel 1000 to stabilize the workpiece 1040, either with or without the non-abrasive material 1010. An external energy source 1200 may transfer energy (e.g., vibratory, acoustical, or electrical energy), for example, through the vessel 1000 and the non-abrasive material 1010 to the abrasive material 1030. As the workpiece 1040 moves in various directions, based on the transferred energy, abrasive impingement by the abrasive material 1030 may occur laterally and result in uniform interior texturing to the surfaces 1020 of the workpiece 1040, as shown in FIG. 2. The vessel 1000 may be physically attached to the external energy source 1200 (e.g., a linear motor, a rotary motor, an electromagnet, or other powering devices) controlled by a controller 1100 that may sense movements of the vessel 1000. To control the external energy source 1200, the controller 1100 may be programmed to consider various factors, such as the desired coarseness of the texture on the surfaces 1020, the relative hardness of the abrasive material 1030 to that of existing coatings on the surfaces 1020 and the surfaces 1020 themselves, and/or the movements of the vessel 1000. Based on these various factors, the controller may adjust vessel movement patterns, durations, or intensity of the energy transfer.

FIG. 2A shows examples of various movements that may be applied to the workpiece 1040 to texturize its surfaces 1020. The view of FIG. 2A is a lateral cross-sectional view 2000. The movements may be generated by the external energy source 1200 coupled to the workpiece 1040 through the vessel 1000. The movements may include rotational movements (clockwise rotations 2012 or counter-clockwise rotations 2014), vibrations 2016, or a combination of both. The workpiece 1040 may also undergo periodic alternating clockwise rotations 2012 and counter-clockwise rotations 2014.

FIG. 2B shows additional views of various movements that may be applied to a workpiece. The view of FIG. 2B is a longitudinal cross-sectional view 2010. In the lateral cross-sectional view 2000 of FIG. 2A, the external energy source 1200 may cause the workpiece 1040 to rotate, vibrate up and down, or rotate and vibrate simultaneously. In the longitudinal cross-sectional view 2010 of FIG. 2B, the clockwise rotations 2012 and counter-clockwise rotations 2014 may cause the abrasive material 1030 to abrade the surfaces 1020 of the workpiece 1040, with arrows 2013, 2015, and 2017 showing the directions of the movement of the abrasive material 1030.

By adjusting the speeds of the rotations and the frequency of the vibrations, the degree of coarseness of the desired texture on the surfaces 1020 may be controlled. The texturization of the surfaces 1020 may include creating a new texture, refurbishing the surfaces 1020 by removing existing coatings and restoring the original texture, and/or polishing the surfaces 1020. The resulting texturized surfaces 1020 may be stochastic and/or diffuse and exhibit improved film adhesion.

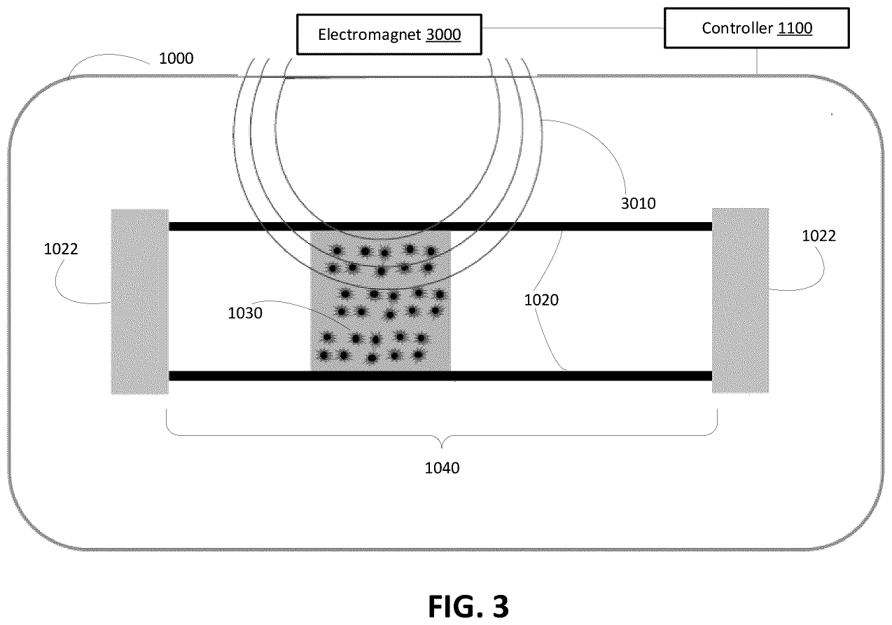

FIG. 3 shows an example of an electromagnet 3000 configured to apply an electromagnetic field 3010 to oscillate the abrasive material 1030 for abrading the surfaces 1020 of the workpiece 1040. Abrading the surfaces 1020 may involve removing a coating from the interior surfaces of the workpiece 1040 and imparting a predetermined texture. This may be achieved by impounding a ferrofluid material within the workpiece 1040 and mobilizing it using an electromagnetic field 3010. For example, the abrasive material 1030 may comprise a ferrofluid material. The ferrofluid material may comprise a ferrofluid and aluminum oxide (Al₂O₃) particles coated or mixed with iron. The iron coating may functionalize the aluminum oxide particles as abrasives and provide fluid uniformity. Non-ferrous particles like silicon carbide (SIC), zirconium dioxide (ZrO₂), or silicon dioxide (SiO₂) may also be used as abrasives. Additionally or alternatively, the abrasive material 1030 may comprise the ferrofluid with suspended abrasive particles (e.g., aluminum oxide, silicon carbide, zirconium dioxide, silicon dioxide, or other abrasive compound).

For example, a ferrofluid may be referred to as a substantially stable colloidal suspension of magnetic particles in a liquid carrier. A ferrofluid material for use in one or more aspects may include a permanent or semi-permanent suspension of magnetic particles in a liquid carrier. The magnetic particles may comprise finely divided magnetite and/or gamma iron oxide particles. Other types of magnetic particles may also be used, such as chromium dioxide, ferrites, e.g., manganese-zinc ferrite, manganese ferrite, nickel ferrite elements, and/or metallic alloys, e.g., cobalt, iron, nickel, and/or samarium-cobalt. The magnetic particles may range in size from about 10 to about 800 angstroms. In some examples, the particles range in size from about 50 to about 500 angstroms, with the average particle size being from about 100 to about 120 angstroms. The magnetic particles are typically coated with one or more layers of surfactant to prevent agglomeration in any particular liquid carrier. Other magnetic particles, in addition to or in place of the above-identified magnetic particles, may be used.

Various liquid carriers may be used as the ferrofluid material. Examples of liquid carriers may include water, silicones, hydrocarbons, both aromatic and aliphatic, such as toluene, xylene, cyclohexane, heptane, kerosene, mineral oils and the like, halocarbons, such as fluorocarbons, fluorinated and chlorinated ethers, esters and derivatives of C₂-C₆ materials, such as perfluorinated polyethers, esters that include di, tri and polyesters, such as azelates, phthalates, sebacates, such as for example, dioctyl phthalates, di-2-theryhexyl azelates, silicate esters, and the like. Other liquid carriers may be used. The ferrofluid material may be mixed with various materials such as alumina, zirconia, silicon carbide, or silicon oxide. Alternatively, iron particles coated with alumina, zirconia, silicon carbide, or silicon oxide may be mixed with the ferrofluid material. For example, particle sizes of alumina, zirconia, silicon carbide, or silicon oxide may range between 220 and 120 angstroms.

A dispersant (e.g., a surfactant) may be used to aid in the dispersion of the magnetic particles. Examples of such dispersants or surfactants may include succinates, sulfonates, phosphated alcohols, long-chain amines, phosphate esters, polyether alcohols, polyether acids, and the like. The surfactant to magnetic particles ratio may range from about 1:2 to about 10:1 by volume. Other ratios are possible.

In a further example, the abrasive material 1030 may comprise no ferrofluid but instead comprise ferrous particles coated with an abrasive compound (e.g., a coating aluminum oxide, silicon carbide, zirconium dioxide, silicon dioxide, or other abrasive compounds).

The application of the electromagnetic field 3010 may be carried out by moving the workpiece 1040 through the electromagnetic field 3010, moving the electromagnetic field 3010 relative to the workpiece 1040, or both. The electromagnetic field 3010 or the workpiece 1040 may be rotated relative to each other. Additionally or alternatively, the magnetic poles of the electromagnetic field 3010 may be reversed cyclically. The endpoint of the coating removal process may be determined by measuring local changes in the electromagnetic field 3010. The hardness of the abrasives relative to the hardness of the coating and the surfaces 1020 of the workpiece 1040 may be variables of the coating removal process. The removal rate of the coating may be tuned by adjusting strength of the electromagnetic field 3010, duration of the electromagnetic field 3010, ratio of the ferrofluid to ferrous particles (e.g., aluminum oxide, silicon carbide, zirconium dioxide, or silicon dioxide), or ratio of the ferrofluid to abrasive particles (e.g., ferrous particles coated with an abrasive compound). Although the coating removal process may be highly effective for cleaning interior surfaces of small diameters or complex-shaped conduits, it may also be used on surfaces that are more easily accessible.

For example, the electromagnet 3000 may be controlled by the controller 1100 to rotate and/or follow contour lines of the workpiece 1040. A robot (e.g., a five-axis robot, not shown) with an electromagnet end effector may be programmed to follow the contour lines of the workpiece 1040. Alternatively or additionally, the workpiece 1040 may be rotated by a robot or the vessel 1000, while the electromagnet 3000 follows the contour lines of the workpiece 1040. Alternatively, a series of electromagnet transducers may be programmed to turn on sequentially, thereby creating an electromagnetic wavefront in the surfaces 1020 of the workpiece 1040.

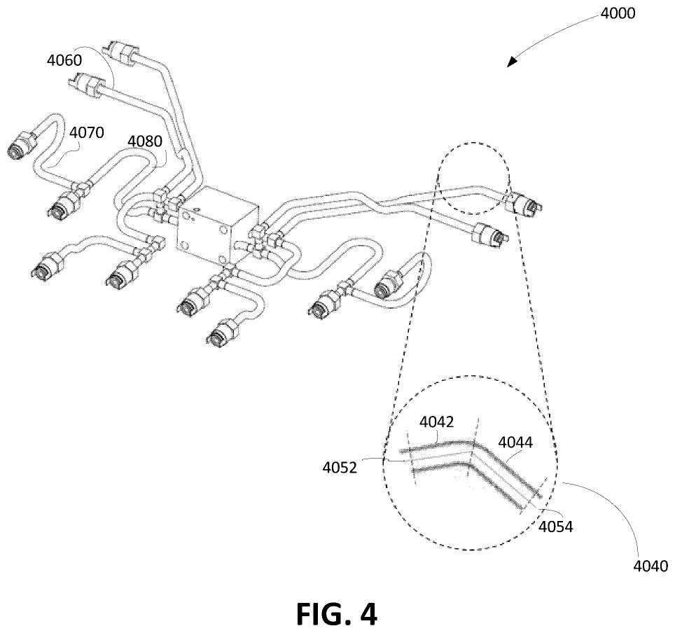

FIG. 4 shows examples of workpieces having irregular shapes. Workpieces 4000 (e.g., 4040, 4060, 4070, 4080) of various shapes may be used in a reaction chamber for manufacturing semiconductor devices. The workpieces 4040, 4060, 4070, and 4080 may comprise one or more of tubes, weldments, or conduits with small diameters (e.g., 0.5 inches or less). The small diameters may range from less than 0.5 inches (12.7 mm) to about 13 mm, with specific ranges between about 4-6 mm, 6-8 mm, 8-10 mm, and 10-13 mm. The workpieces 4040, 4060, 4070, and 4080 may have straight or complex geometry (e.g., one or more corners, bends, arcs, internal structures, or other geometrical features). Parts of the workpieces 4040, 4060, 4070, and 4080 may have non-circular flow areas and/or variable flow areas. For example, the workpiece 4040 (e.g., a conduit) is not straight and may comprise at least two portions 4042 and 4044, each of which is right cylindrical-shaped. The at least two portions 4042 and 4044 may have axis 4052 and axis 4054, respectively, each axis including a line segment joining two centers of two parallel circular bases of each right cylindrical-shaped portion. The axis 4052 and axis 4054 may not be colinear. This non-colinear arrangement may make it difficult to obtain a clear line of sight from an entry end of the portion 4042 and to an exit end of the portion 4044. Furthermore, accessing the interior surfaces of workpieces with small diameters and/or irregular shapes for texturizing may be challenging.

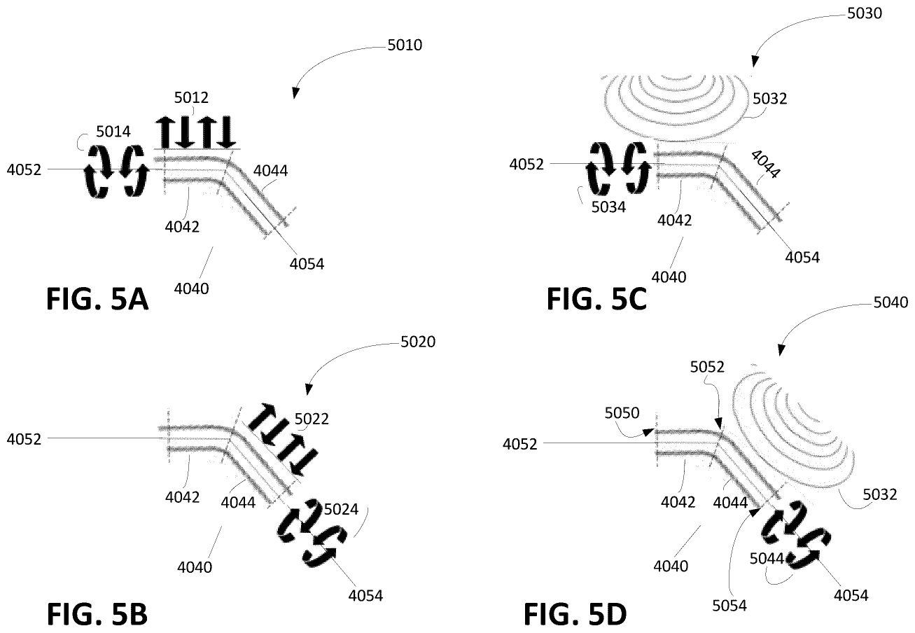

FIGS. 5A, 5B, 5C, and 5D show examples of texturizing procedures that may be carried out on a workpiece, such as the irregular-shaped workpiece 4040 shown in FIG. 4. These procedures may comprise several different setups to texturize the interior surfaces of the workpiece 4040, which may be difficult to access due to small diameters and/or complex shapes. To texturize the interior surfaces of the workpiece 4040, a material (e.g., abrasive material 1030) may be injected into the workpiece 4040's cavity and sealed to hold the material. In FIG. 5A, setup 5010 may be employed to vibrate (e.g., as shown by arrows 5012) the portion 4042 in a direction perpendicular to one or more inside walls of the portion 4042 while simultaneously causing it to rotate (e.g., as shown by arrows 5014) about axis 4052 for a first duration of time. The first duration of time may be proportional to a volume of the portion 4042. The simultaneous vibration and rotation may result in the abrasive material 1030 abrading the inside walls of the portion 4042.

After the first duration of time, another setup 5020 of FIG. 5B may be utilized to vibrate (e.g., as shown by arrows 5022) the portion 4044 in a direction perpendicular to one or more inside walls of the portion 4044 while causing it to rotate (e.g., as shown by arrows 5024) about axis 4054 for a second duration of time. The second duration of time may also be proportional to the volume of the portion 4044, and the rotation may be periodically alternating clockwise rotations and counter-clockwise rotations. This simultaneous vibration and rotation of the portion 4044 may also cause the abrasive material 1030 to abrade the inside walls of the portion 4044. The controller 1100 may be programmed to change setups for texturizing different portions of the workpiece. Once texturizing of all the portions is complete, the texturizing procedures for the workpiece 4040 may be concluded.

Alternatively, a setup 5030 of FIG. 5C may be used to simultaneously apply an electromagnetic field 5032 and cause the portion 4042 to rotate (e.g., as shown by arrows 5034) about the axis 4052 for a first duration of time. The application of the electromagnetic field 5032 may cause, for example, the abrasive material 1030 (e.g., a ferrofluid and Al₂O₃ particles coated or mixed with iron) to abrade the one or more inside walls of the portion 4042. After the first duration of time, a setup 5040 of FIG. 5D may simultaneously apply the electromagnetic field 5032 and cause the portion 4044 to rotate (e.g., as shown by arrows 5044) about the axis 4054 for a second duration of time. Alternatively, the electromagnetic field 5032 may be applied evenly around the external surfaces of the portions 4042/4044 by following their contour lines in a circular manner (e.g., as shown by arrows 5034 or 5044 respectively). Thus, the portions 4042/4044 may not move while the electromagnetic field 5032 is applied.

To abrade the inner walls of the portions 4042/4044, the electromagnetic field 5032 may be applied repeatedly between their respective ends 5050/5052 and 5052/5054 for durations proportional to their volumes. This may be achieved by a robot (e.g., a five-axis robot) with an electromagnet end effector programmed to follow the contour lines of the portions 4042/4044, or by using a cubic container with electromagnet transducers that may turn on sequentially to create a wavefront inside the portions 4042/4044. The abrasive material 1030 (a mixture of ferrofluid and Al₂O₃ particles coated or mixed with iron) mobilized by the electromagnetic field 5032 may cause the desired abrasion.

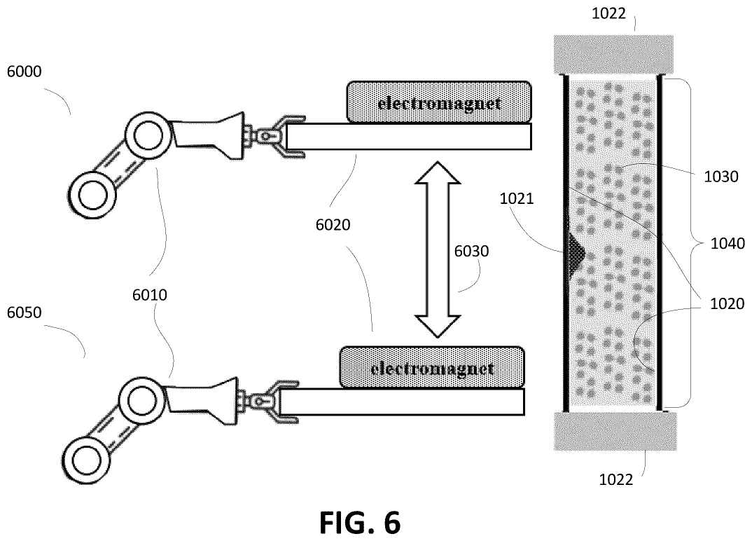

FIG. 6 shows an example of a robot equipped with an electromagnet end effector. The electromagnet end effector 6020, controlled by the robot 6010 (e.g., a five-axis robot), may oscillate between two different positions 6000/6050. The oscillation movement, represented by arrow 6030, may effectively mobilize magnetic particles that are suspended in a ferrofluid, such as abrasive material 1030. As a result, the mobilized magnetic particles may abrade the surfaces 1020 of the workpiece 1040, and progressively remove any coatings 1021 or patina of non-native material that may exist on the surfaces 1020, thereby restoring their original texture.

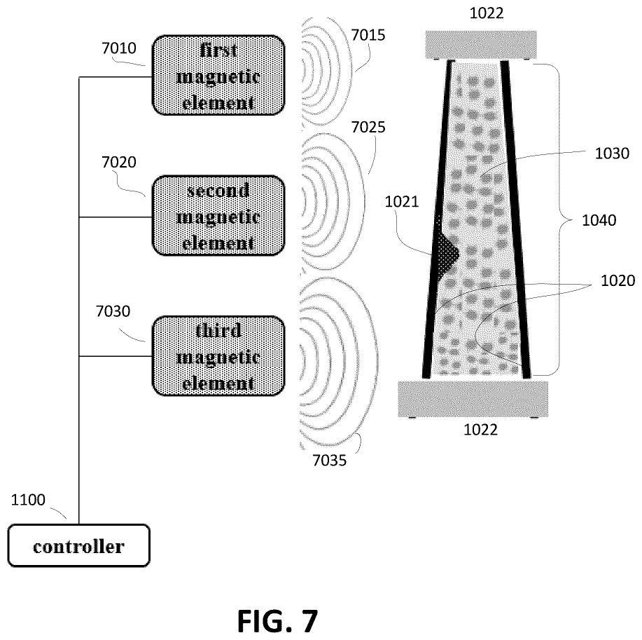

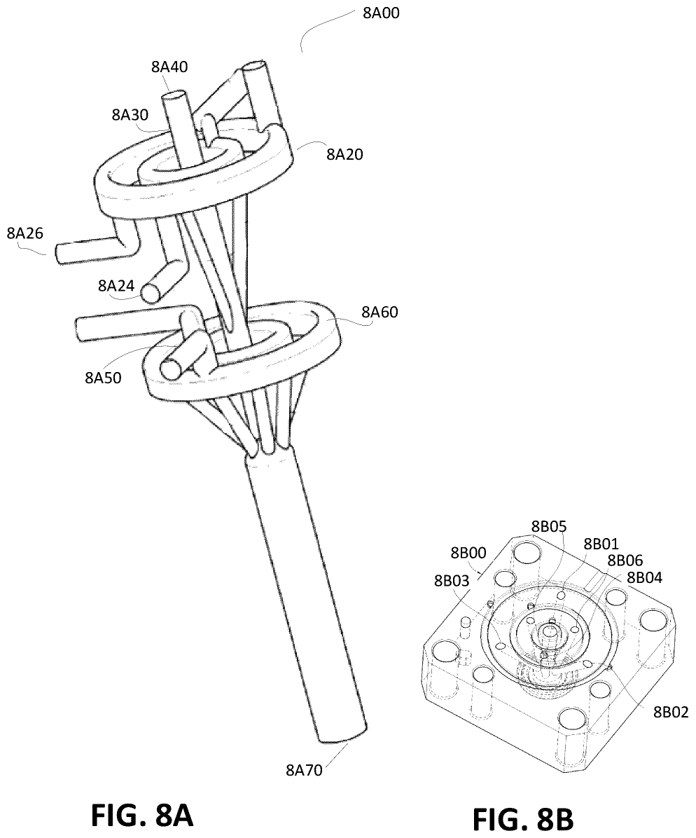

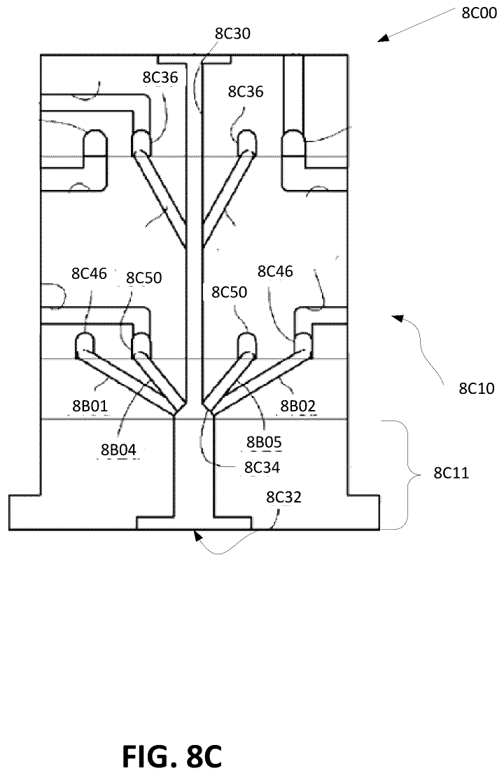

FIG. 7 shows an example of a plurality of magnetic elements with variable electromagnetic fields for texturizing non-uniform shaped parts. The plurality of magnetic elements includes the first, second, and third magnetic elements 7010, 7020, and 7030, which may be controlled by the controller 1100 to generate varying strengths of electromagnetic fields 7015, 7025, and 7035, respectively. Each of the magnetic elements 7010, 7020, and 7030 may be adjusted to generate a selectable intensity of an electromagnetic field. The workpiece 1040 may be comprised of non-uniform shaped parts, such as a manifold shown in FIGS. 8A-8C. To create a wavefront inside the non-uniform shaped parts, the controller 1100 may turn on the first, second, and third magnetic elements 7010/7020/7030 sequentially. Alternatively, the controller 1100 may cyclically vary the strength (or intensity) of the magnetic elements 7010, 7020, and 7030 in a way that corresponds to the location of the non-uniform shaped parts relative to the magnetic elements 7010, 7020, and 7030. The abrasive material 1030 that is mobilized by the electromagnetic fields 7015/7025/7035 may gradually remove any coatings 1021 or patina of non-native material that may exist on the surfaces 1020, thereby restoring their original texture.

FIG. 8A shows an example of a flow path through a manifold. For example, the manifold may have various internal channels 8A00 having non-uniform shaped parts. The internal channels 8A00 may comprise a series of pulsed valves that may be used to introduce different gases or gas mixtures into a reaction chamber in a precise and controlled manner. For example, a distribution channel 8A20 for inert gas may supply two inert gas passageways, 8A24 and 8A26, which connect to a bore 8A30 at different angular positions along its longitudinal axis. The internal channels 8A00 may also include a reactant gas inlet 8A50 that is connected to a reactant gas distribution channel 8A60, which may intersect the longitudinal axis of the bore 8A30. The continuous flow of inert gas through the inlet 8A40 may serve multiple purposes, including preventing upward diffusion of the reactants, creating a gas phase barrier (i.e., a diffusion barrier) between the reactant plugs or pulses, and pushing the plugs down toward an outlet 8A70 for distribution into a reactor via a showerhead.

FIG. 8B shows a top isometric view of a lower block 8B00 of the manifold, which may include several reactant gas supply channels 8B01-8B06. These reactant gas supply channels 8B01-8B06 may have a diameter slightly smaller than or equal to their associated distribution channel. To be more specific, a diameter of the reactant gas supply channels 8B01-8B06 may be between 25% and 100% of the diameter of the distribution channel, with the ideal range being between 40% and 60%. This configuration may generate back pressure in each distribution channel, ensuring that the vapors may be uniformly distributed across all the reactant gas supply channels linked to the distribution channel.

FIG. 8C is a schematic view of a reactor 8C00 including a manifold 8C10. For example, the manifold 8C10 is illustrated along with the reactant gas supply channels 8B01, 8B02, 8B04, and 8B05, which may merge with a bore 8C30. A manifold body 8C11 may be connected to the upstream of a reaction chamber (not shown). A non-circular flow area, outlet 8C32 of the bore 8C30 may communicate with a reactant injector, such as a showerhead dispersion mechanism, to transfer vapors from the manifold 8C10 into the reaction space (not shown) below a showerhead. The manifold block 8C11 may also connect via various valves and gas lines to inert gas and reactant sources. Furthermore, upper reactant distribution channels 8C36 can connect to external gas lines and control valves, while lower reactant distribution channels 8C46 and 8C50 may connect to reactant sources (not shown). To prevent upstream diffusion of reactant, a narrower portion of the bore 8C30, which is the upstream of a transitional flow area (e.g., a tapered portion 8C34), may be filled with flowing inert gas.

Conventional methods such as blasting, hydrohonning, or abrasive honing may be often ineffective or impractical for removing unwanted coatings or patina from the interior surfaces of complex-shaped parts such as various channels (see FIGS. 8A-8C) of the manifold 8C10. However, the coating removal techniques described here may be highly effective in cleaning the interior surfaces of the various channels shown in FIGS. 8A-8C.

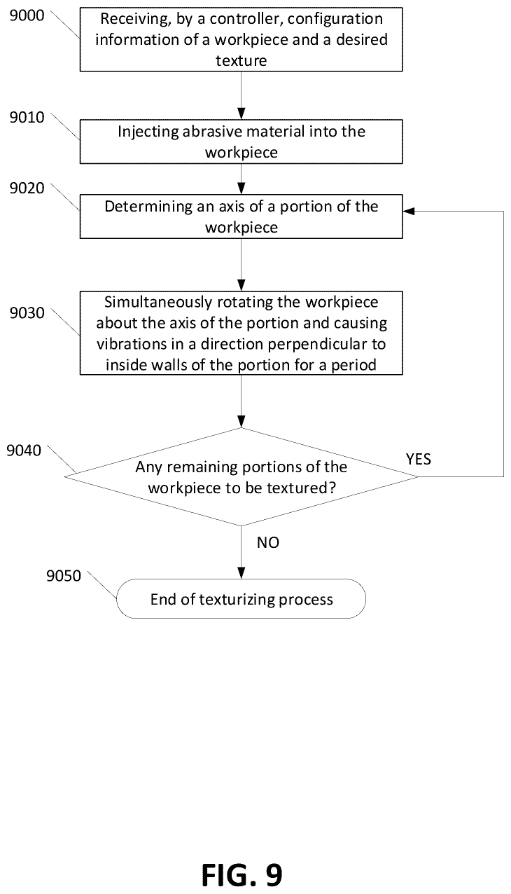

FIG. 9 shows a flowchart outlining the steps involved in an example method for texturizing a workpiece. For convenience, FIG. 9 is described by way of an example in which the steps are performed by the controller 1100. One, some, or all steps of the example method of FIG. 9, or portions thereof, may be performed by one or more robots (e.g., a five-axis robot). One, some, or all steps of the example method of FIG. 9 may be omitted, performed in other orders, and/or otherwise modified, and/or one or more additional steps may be added.

At step 9000, the controller 1100 may receive configuration information about a workpiece, including its geometry, a desired texture (e.g., a specific coarseness level or coarseness degree), a relative hardness of abrasive material to that of coating on the surfaces of the workpiece and the surfaces themselves, or movements of the workpiece. Based on this information, for example, the controller 1100 may adjust a duration of the treatment of the workpiece. Additionally or alternatively, the controller 1100 may adjust a degree of energy transferred to the workpiece, and/or the movement pattern of the workpiece. Additionally or alternatively, the controller may select a first abrasive material with a first abrasiveness degree over a second abrasive material with a second abrasiveness degree.

At step 9010, abrasive material, such as abrasive dry grit or abrasive aqueous slurry, may be injected into the cavity of the workpiece. The abrasive material may be injected through one opening or multiple openings of the workpiece. The abrasive material may or may not completely fill the cavity. In one example, leaving the cavity only partially filled permits the abrasive material more space to move before contacting the interior walls of the workpiece.

At step 9020, the axis of a right cylindrical-shaped portion of the workpiece may be determined by identifying the line segment connecting the centers of the two parallel circular bases of the right cylindrical portion. The axis of the portion of the workpiece and the portion's length may be used to determine a duration of a period of time for the abrading process for that portion of the workpiece.

At step 9030, the workpiece may be simultaneously rotated about the axis of the right cylindrical portion and vibrated perpendicular to its inside walls for a specified period. Alternatively, the external surfaces of the workpiece may be evenly subjected to an electromagnetic field by following their contour lines in a circular manner. Thus, the workpiece itself is not moved. The processing of step 9030 may be performed for the specified period. In one example, the specified period, for each portion of the workpiece, may be the same. In other examples, the specified period, for each portion of the workpiece, may be different. In further examples, some of the specified periods may be equal to each other and different from other specified periods.

In step 9040, after the specified period, at step 9040, if there are no more portions of the workpiece left to be processed, the texturizing process concludes at step 9050. At step 9040, if there are more portions to be processed, the texturizing process may return to step 9020 and repeats steps 9030 and 9040.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A method comprising:
injecting a first material into a cavity of a workpiece, wherein the workpiece comprises one or more interior walls that form the cavity;
encasing the workpiece in a vessel; and
transferring energy, via the vessel, to the first material in the cavity such that the first material abrades the one or more interior walls of the workpiece.

2. The method of claim 1, wherein the transferring energy comprises:
powering a linear motor; or
powering a rotary motor.

3. The method of claim 1, wherein the first material comprises an abrasive grit or an abrasive slurry, the method further comprising:
at least partially filling the vessel with a second material, wherein the second material is less abrasive than the first material.

4. The method of claim 1, wherein the first material comprises a ferrofluid material, and wherein the ferrofluid material comprises:
a ferrofluid mixed with one of alumina, zirconia, silicon carbide, or silicon oxide; or
a ferrofluid mixed with iron particles coated with one of alumina, zirconia, silicon carbide, or silicon oxide.

5. The method of claim 1, further comprising injecting a second material into the vessel, wherein:
the first material comprises one of alumina, zirconia, silicon carbide, or silicon oxide;
the first material is more abrasive than the second material; and
the second material comprises one of a synthetic fluoropolymer of tetrafluoroethylene, nylon, or polyethylene.

6. The method of claim 1, wherein the one or more interior walls of the workpiece form a tube with a diameter less than 13 mm, and wherein the tube includes one or more bends, non-circular flow areas, or variable flow areas.

7. The method of claim 1, further comprising:
sealing openings of the cavity of the workpiece after injecting the first material so that the workpiece holds the first material inside the cavity.

8. The method of claim 1, wherein the transferring energy comprises vibrating the vessel and periodically alternating clockwise rotations and counter-clockwise rotations of the vessel.

9. The method of claim 1,
wherein the transferring energy comprises simultaneously applying an electromagnetic field to the workpiece and rotating the vessel,
wherein the first material comprises ferrous particles coated with an abrasive coating, and
wherein the electromagnetic field causes the first material to abrade the one or more interior walls of the workpiece with the abrasive coating of the ferrous particles.

10. The method of claim 1,
wherein the abrading the one or more interior walls comprises uniformly texturizing a surface of the one or more interior walls of the workpiece, and
wherein the uniformly texturizing comprises one of restoring a pre-existing texture on the surface, creating a new texture on the surface, or polishing the surface.

11. The method of claim 1, further comprising:
determining a coarseness degree, of a desired texture, on a surface of the one or more interior walls of the workpiece; and
based on the determining, adjusting at least one of an abrasiveness degree of the first material, a duration of the transferring energy, a movement pattern of the vessel, or a degree of the transferred energy.

12. The method of claim 1, wherein the transferring energy comprises:
determining an axis of a portion of the workpiece, wherein the workpiece comprises a plurality of portions, each portion having a right cylindrical shape, joined together to form an irregular shape, each portion having an axis that is a line segment joining two centers of two parallel circular bases of each right cylindrical-shaped portion; and
simultaneously, for at least one portion of the plurality of portions:
vibrating the vessel in a direction perpendicular to an inside wall of the at least one portion of the plurality of portions; and
rotating the vessel such that the workpiece rotates about the axis of the at least one portion,
wherein a duration of simultaneously vibrating the vessel and rotating the vessel is proportional to a volume of the at least one portion.

13. The method of claim 1, wherein the transferring energy comprises:
determining an axis of a portion of the workpiece, wherein the workpiece comprises a plurality of portions, each portion having a right cylindrical shape, joined together to form an irregular shape, each portion having an axis that is a line segment joining two centers of two parallel circular bases of each right cylindrical-shaped portion;
applying an electromagnetic field in a direction perpendicular to one or more inside walls of a portion of the plurality of portions, wherein the first material in the cavity of the workpiece comprises a ferrofluid material;
rotating the vessel such that the workpiece rotates about the axis of the portion at the same time as the applying; and
after a period, processing a next portion of the plurality of portions by repeating the determining, applying, and rotating until all portions of the plurality of portions are processed, wherein the period is proportional to a volume of a corresponding portion.

14. A method comprising:
injecting a ferrofluid material in a cavity of a workpiece, wherein the workpiece comprises a plurality of portions, each portion having a right cylindrical shape, joined together to form an irregular shape of the workpiece, each portion having an axis that is a line segment joining two centers of two parallel circular bases of each right cylindrical-shaped portion;
determining an axis of a portion of the plurality of portions;
rotating the workpiece about the axis of the portion;
applying an electromagnetic field along a contour line of the portion at the same time as the rotating; and
after a period, processing a next portion of the plurality of portions by repeating the determining, rotating, and applying until all of the plurality of portions are processed, wherein the period is proportional to a volume of a corresponding portion.

15. The method of claim 14, wherein the applying the electromagnetic field comprises programming a five-axis robot with an electromagnet end effector to follow the contour line of the portion.

16. The method of claim 14, wherein the applying the electromagnetic field comprises:
programming a series of electromagnet transducers to turn on sequentially, thereby creating a wavefront inside the portion; or
cyclically varying strength of the series of electromagnet transducers, wherein the strength of each of the series of electromagnet transducers is adjustable.

17. A method comprising:
injecting a ferrofluid material in a cavity of a workpiece, wherein the workpiece comprises a plurality of portions, each portion having a right cylindrical shape, joined together to form an irregular shape of the workpiece, each portion having an axis that is a line segment joining two centers of two parallel circular bases of each right cylindrical-shaped portion;
applying an electromagnetic field along a contour line of a portion of the plurality of portions; and
after a period, processing a next portion of the plurality of portions by repeating the applying until all of the plurality of portions are processed, wherein the period is proportional to a volume of a corresponding portion.

18. The method of claim 17, wherein the applying the electromagnetic field comprises moving, by a robot, an electromagnet along the contour line of the portion while rotating or vibrating the portion about an axis of the portion.

19. The method of claim 17, further comprising placing the workpiece in a vessel, wherein the vessel is moved or vibrated by at least one of a linear motor or a rotary motor.

20. The method of claim 17, wherein the ferrofluid material comprises:
a ferrofluid and suspended particles of one of alumina, zirconia, silicon carbide, or silicon oxide; or
a ferrofluid and suspended iron particles coated with one of alumina, zirconia, silicon carbide, or silicon oxide.
